(19) United States
(12) Patent Application Publication
(10) Pub. No.: US 2013/0320438 A1
(43) Pub. Date: Dec. 5, 2013

(54) SEMICONDUCTOR DEVICE AND METHOD FOR MANUFACTURING THE SAME

(71) Applicant: SK HYNIX INC., Icheon (KR)

(72) Inventor: Shin Gyu CHOI, Seoul (KR)

(73) Assignee: SK HYNIX INC., Icheon (KR)

(21) Appl. No.: 13/649,946

(22) Filed: Oct. 11, 2012

(30) Foreign Application Priority Data
May 29, 2012 (KR) 10-2012-0056910

(51) Int. Cl. H01L 29/78; H01L 21/336

(52) U.S. Cl. 257/330; 438/270; 257/E29.262; 257/E21.41

(57) ABSTRACT

A semiconductor device comprises a gate electrode buried in a trench within a semiconductor substrate, a first sealing insulating film disposed over the gate electrode and the semiconductor substrate, an ion-implanting region disposed in portions of the semiconductor substrate adjacent to sidewalls of the trench, and a second sealing insulating film formed over the first sealing insulating film to bury the trench.

### CROSS-REFERENCE TO RELATED APPLICATION

The present application claims priority to Korean patent application No. 10-2012-0056910 filed on May 29, 2012, which is incorporated by reference in its entirety.

### BACKGROUND OF THE INVENTION

The present invention relates generally to a semiconductor device and a method for manufacturing the same, and more particularly to a technology for preventing gate oxidation and contamination of a gate during an ion-implanting process and reducing a stress of the semiconductor device.

Most electronic appliances today include semiconductor devices. Semiconductor devices include electronic elements such as transistors, resistors and capacitors, etc. The electronic elements are designed to perform partial functions of the electronic appliances which are integrated on a semiconductor substrate. For example, electronic appliances such as computers or digital cameras include memory chips for storing information and processing chips for processing information in the memory chips. These processing chips include the electronic elements integrated on the semiconductor substrate.

On the other hand, semiconductor devices need to be more highly integrated in order to satisfy the high performance and low prices that users demand. As the degree of integration of semiconductors device is increased, design rules are scaled down and patterns of the semiconductor device are miniaturized. As semiconductor devices become miniaturized and highly integrated, the total size of the chip may be increased in proportion to the increment in the memory capacity, but the dimensions of a cell area in which patterns of the semiconductor device are formed in is substantially reduced. Accordingly, since many patterns should be formed in a defined area in order to ensure the desired memory capacity, fine patterns where the critical dimensions are scaled down should be formed.

Various fine pattern formation methods have been developed to lower the threshold value of the resolution. These methods include a method using a phase shift mask as a photo mask, a contrast enhancement layer (CEL) method which forms a separate layer for improving an image contrast on a thin wafer, a tri layer resister (TLR) method where an intermediate layer such as a spin on glass (SOG) is interposed between two photoresist layers, and a silylation method which selectively implants silicon in the upper portion of the photoresist layer.

Meanwhile, with the increasing integration degree of semiconductor devices, the length of a channel is gradually reduced so that high-density channel doping is required to guarantee transistor characteristics, and deterioration of refresh characteristics resulting from the high-density channel doping is an outstanding issue to resolve. To accomplish this, there is a newly proposed technology for reducing bit line capacitance in which a recessed gate structure is configured as a buried gate structure so that a gate is formed at a lower part of a bit line and both capacitance between the gate and the bit line and total capacitance of the bit line are reduced.

Generally, in order to obtain a buried gate, a semiconductor substrate is etched to a given depth to form a trench. A gate metal is formed over the upper portion to bury the trench, and an etch-back process is performed so that gate metal with a given thickness may remain in the trench. During the etch-back process, variation in the etched-back depth may occur.

### BRIEF SUMMARY OF THE INVENTION

Various embodiments of the present invention are directed to providing a technology for preventing degradation of a semiconductor device by performing an etch-back process on a buried-type gate and forming separate insulating films that can reduce a stress within the buried-type gate, and performing a tilt ion-implantation process so that a channel has a uniform vertical overlap with an adjacent gate.

According to an exemplary embodiment of the present invention, a semiconductor device comprises: a gate electrode buried in a trench within a semiconductor substrate; a first sealing insulating film disposed over the semiconductor substrate including the gate electrode; an ion-implanting region disposed in a portion of the semiconductor substrate adjacent to sidewalls of the trench; and a second sealing insulating film formed over the first sealing insulating film and filling the trench.

The semiconductor device further comprises a gate oxide film may be formed on an inner surface of the trench.

A portion of the ion-implanted region may be overlaps with a portion of the gate electrode in a vertical direction.

The first sealing insulating film and the second sealing insulating film may be include a nitride film.

The first sealing insulating film may be had a thickness ranging from 50 Å to 100 Å.

According to another aspect of an exemplary embodiment of the present invention, a method for manufacturing a semiconductor device comprises: forming a gate electrode in a trench in a semiconductor substrate that includes a cell region and a peripheral circuit region, the trench having an upper portion and a lower portion, the gate electrode being provided in the lower portion of the trench; forming a first sealing insulating film over the semiconductor substrate including the gate electrode; forming an ion-implanting region in the semiconductor substrate adjacent to sidewalls of the trench; and forming a second sealing insulating film over the first sealing insulating film to fill the upper portion of the trench, thereby obtaining a buried gate.

Before forming the gate electrode, the method for manufacturing a semiconductor device may be comprise forming a gate oxide film on an inner surface of the trench.

The forming-a-gate-electrode may be comprise: forming a gate electrode layer within the trench; and performing an etch-back process on the gate electrode layer.

The first sealing insulating film is formed to have a thickness ranging from 40 Å to 100 Å.

The step of forming an ion implanting region may be performed using a tilt ion-implantation process.

The step of forming an ion-implanting region may be performed by a spin ion-implantation process.

The forming-an-ion-implanting-region may be comprise forming a mask pattern over the semiconductor substrate in the peripheral circuit region; and performing an ion-implanting process using the mask pattern as a mask.

The step of forming an ion-implanted region may be performed using a tilt ion implantation process with a tilt angle that implants ions to form a channel region in a portion of the semiconductor that is adjacent the gate electrode and overlaps a portion of the gate electrode in a vertical direction.

The step of forming the gate electrode may be comprise forming a gate electrode layer within the trench and performing an etch-back process on the gate electrode layer to a depth where, in the subsequent step of forming an ion-implanting region, portions of the first sealing insulating film disposed over the gate electrode and an upper surface of the semiconductor substrate mask the upper surface of the gate electrode.

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1 illustrates a semiconductor device according to an embodiment of the present invention, wherein (i) shows a cross-sectional view of a cell region and (ii) shows a cross-sectional view of a peripheral circuit region; and

FIGS. 2a to 2e illustrate a method for manufacturing a semiconductor device, wherein (i) shows a cross-sectional view of a cell region and (ii) shows a cross-sectional view of a peripheral circuit region.

### DESCRIPTION OF EMBODIMENTS

Embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments of the present invention should not be construed as being limited to the particular shapes of regions illustrated herein, but may include deviations in shapes that result, for example, from manufacturing. In the drawings, lengths and sizes of layers and regions may be exaggerated for clarity. Like reference numerals in the drawings denote like elements.

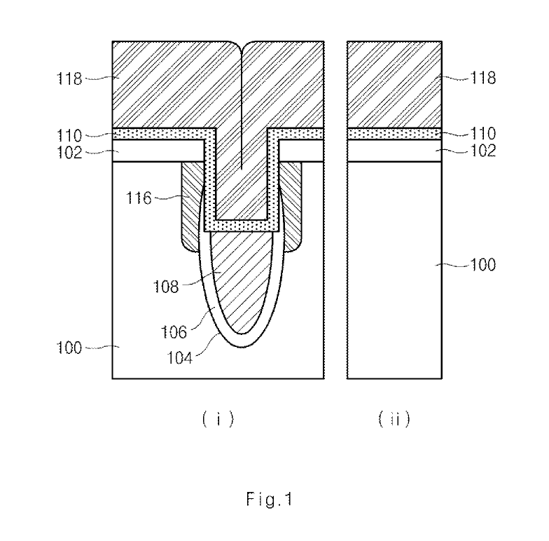

FIG. 1 illustrates a semiconductor device according to an embodiment of the present invention, wherein (i) shows a cross-sectional view of a cell region and (ii) shows a cross-sectional view of a peripheral circuit region.

Referring to FIG. 1, the semiconductor device includes a gate oxide film 106 formed on the inner surface of a trench 104 within a semiconductor substrate 100, a gate electrode 108 formed over the gate oxide film 106 and buried in the trench 104, an ion-implanting region 116 disposed in portions of the semiconductor substrate 100 adjacent to sidewalls of the trench 104, a first sealing insulating film 110 disposed over the gate electrode 108 and the semiconductor substrate 100, and a second sealing insulating film 118 formed over the first sealing insulating film 110 to bury the trench 104. A mask pattern 102 may be further disposed over the first semiconductor substrate 100 in order to define the trench 104.

In an exemplary embodiment, the first sealing insulating film 110 and the second sealing insulating film 118 include a nitride film. The first sealing insulating film 110 has a thickness ranging from 40 Å to 100 Å, and the second sealing insulating film 118 has a thickness of 650 Å. The second sealing insulating film 118 may have a tolerance of plus or minus about 50 Å. The thickness of the first sealing insulating film 110 may differ between various embodiments depending on variables such as a width of the trench 104, a thickness of the gate oxide film 104, the degree to which gate electrode 108 is etched back. In addition, the thickness of the first sealing insulating film 110 may be determined so that the first sealing insulating film 110 prevents gate electrode 108 from being exposed to ions during an ion implantation process performed on ion-implanting region 116. The thickness of the second sealing insulating film 118 is not limited to 650 Å. For example, the depth of the trench 104 may be different in various embodiments, so the thickness of a portion of the second sealing insulating film 118 filling trench 104 may vary accordingly.

The first sealing insulating film 110 prevents the gate electrode 108 from being oxidized and contaminated during an ion-implanting process performed on the semiconductor substrate 100, and serves as a buffer that prevents the surface of the semiconductor from being damaged by the ion-implanting process.

The ion-implanting region 116 is disposed in portions of the semiconductor substrate 100 adjacent to sidewalls of the trench 104 to vertically overlap with the gate electrode 108, thereby reducing resistance of a channel part, which improves properties of the semiconductor device.

A method for manufacturing a semiconductor device having the above-described structure according to an embodiment of the present invention is as follows.

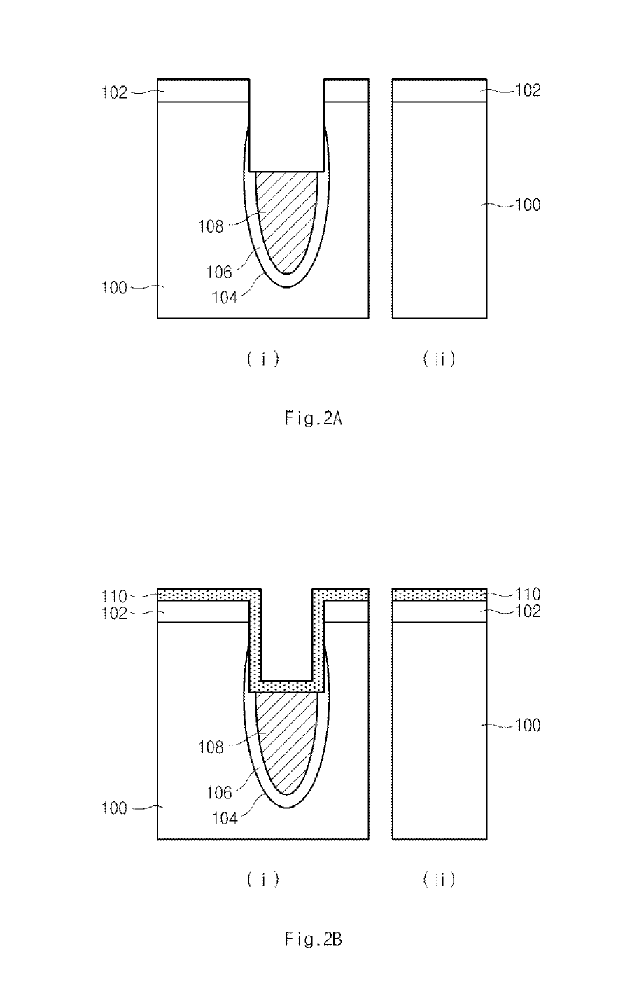

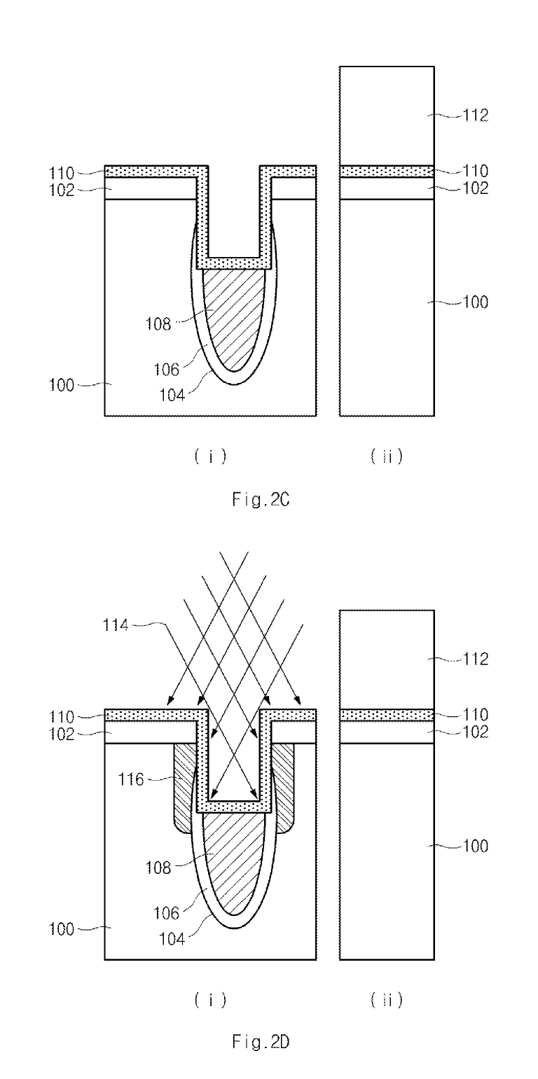

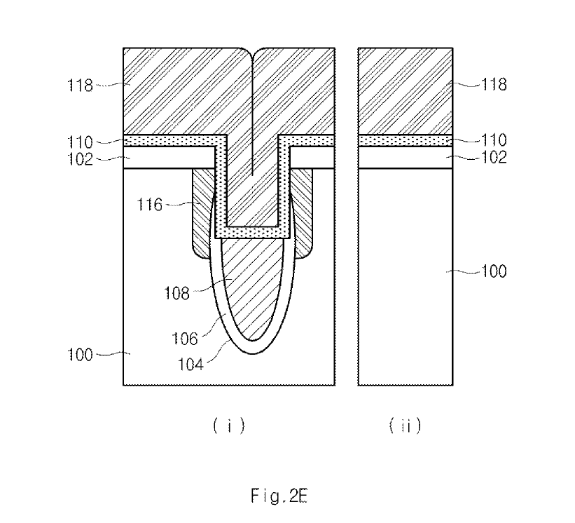

FIGS. 2a to 2e illustrate a method for manufacturing a semiconductor device, wherein (i) shows a cross-sectional view of a cell region and (ii) shows a cross-sectional view of a peripheral circuit region.

Referring to FIG. 2a, mask pattern 102 is formed over semiconductor substrate 100 including a cell region (i) and a peripheral circuit region (ii). The semiconductor substrate 100 is etched using mask pattern 102 as an etch mask to form trench 104. A gate oxide film 106 is formed on the inner surface of the trench 104. A gate electrode material is formed within the trench 104, and an etch-back process is performed to form the gate electrode 108. The etch-back process is performed to etch the gate electrode sufficiently in consideration of diffusion of a storage electrode contact plug (not shown) formed in a subsequent process. The gate electrode material may include tungsten.

Referring to FIG. 2b, the first sealing insulating film 110 is formed over the gate electrode 108 and the semiconductor substrate 100. The first sealing insulating film 110 includes a nitride film, and may have a thickness ranging from 40 Å to 100 Å. The first sealing insulating film 110 prevents the gate electrode 108 from being oxidized and contaminated during a subsequent ion-implanting process, and serves as a buffer that prevents the surface of the semiconductor from being damaged by the ion-implanting process.

As shown in FIG. 2c, a mask pattern 112 is formed over portions of the peripheral circuit region (ii), but not over portions of the cell region (i). The mask pattern 112 is formed in the peripheral circuit region (ii) in order to prevent ions from being implanted in a transistor channel part of the peripheral circuit region (ii).

As shown in FIG. 2d, an ion-implanting process 114 is performed on the cell region (i) using the mask pattern 112 as a mask to form the ion-implanting region 116 in a portion of the semiconductor substrate 100 adjacent to sidewalls of the trench 104. A material used in the ion-implanting process 114 may be an n-type dopant including a phosphorus (ph). The ion-implanting process 114 is performed at an acute angle to the upper surface of the semiconductor substrate 100 adjacent to the sidewalls of the trench 104. For example, as seen in FIG. 2d, ions are implanted at an angle of about 30 degrees with respect to upper sidewalls of trench 104. In an embodiment, variables such as the thickness of layers, the angle of ion implantation, and the depth and width of the trench 104 may be determined so that ions are implanted into ion-implantation region 116 overlapping gate electrode 108 while shielding gate electrode 108 from the ions.

When the width of the trench 104 is relatively narrow or the depth of the trench 104 is relatively deep giving the trench a high aspect ratio, a spin ion-implantation process can be performed in addition to a tilt ion-implantation process. The ion-implanting region 116 is formed in portions of the semiconductor substrate 100 adjacent to the sidewalls of the trench 104 to vertically overlap with the gate electrode 108, thereby providing low resistance a channel part to improve the properties of the semiconductor device.

Referring to FIG. 2e, after the mask pattern 112 is removed, a second sealing insulating film 118 is formed over the first sealing insulating film 110. Since the first sealing insulating film 110 and the second sealing insulating film 118 are formed on two separate steps, less stress is applied to the semiconductor. The first sealing insulating film 110 acts as a buffer to reduce the amount of stress that subsequently formed second sealing insulating film 118 applies to the semiconductor. Reducing the stress helps to prevent generating a leakage current.

Accordingly, in embodiments of the present invention, the first sealing insulating film is formed over a buried-type gate to prevent the gate electrode from being oxidized and contaminated, and to prevent surfaces of the semiconductor from being damaged by an ion-implanting process. Moreover, the ion-implanting region may be formed in the semiconductor substrate adjacent to the trench surface of the buried-type gate to lower resistance in a channel. Also, the second sealing insulating film is formed after the first sealing insulating film is formed so that stress applied to the semiconductor substrate may be relieved, preventing generation of a leakage current to improve the properties of the semiconductor device.

The above embodiments of the present invention are illustrative and not limitative. Various alternatives and equivalents are possible. The invention is not limited by the embodiments described herein. Nor is the invention limited to any specific type of semiconductor device. Other additions, subtractions, or modifications are obvious in view of the present disclosure and are intended to fall within the scope of the appended claims.

What is claimed is:

1. A semiconductor device, comprising:
a gate electrode buried in a trench within a semiconductor substrate;
a first sealing insulating film disposed over the semiconductor substrate including the gate electrode;
an ion-implanting region disposed in a portion of the semiconductor substrate adjacent to sidewalls of the trench; and
a second sealing insulating film formed over the first sealing insulating film and filling the trench.

2. The semiconductor device according to claim 1, further comprising a gate oxide film formed on an inner surface of the trench.

3. The semiconductor device according to claim 1, wherein a portion of the ion-implanted region overlaps with a portion of the gate is electrode in a vertical direction.

4. The semiconductor device according to claim 1, wherein the first sealing insulating film and the second sealing insulating film include a nitride film.

5. The semiconductor device according to claim 1, wherein the first sealing insulating film has a thickness ranging from 50 Å to 100 Å.

6. A method for manufacturing a semiconductor device, the method comprising:
forming a gate electrode in a trench in a semiconductor substrate that includes a cell region and a peripheral circuit region, the trench having an upper portion and a lower portion, the gate electrode being provided in the lower portion of the trench;
forming a first sealing insulating film over the semiconductor substrate including the gate electrode;
forming an ion-implanting region in the semiconductor substrate adjacent to sidewalls of the trench; and
forming a second sealing insulating film over the first sealing insulating film to fill the upper portion of the trench, thereby obtaining a buried gate.

7. The method according to claim 6 further comprising, before forming the gate electrode, forming a gate oxide film on an inner surface of the trench.

8. The method according to claim 6, wherein the step of forming the gate-electrode comprises:
forming a gate electrode layer within the trench; and
performing an etch-back process on the gate electrode layer.

9. The method according to claim 6, wherein the first sealing insulating film has a thickness ranging from 40 Å to 100 Å.

10. The method according to claim 6, wherein the step of forming an ion implanting region is performed using a tilt ion-implantation process.

11. The method according to claim 6, wherein the step of forming an ion-implanting region is performed by a spin ion-implantation process.

12. The method according to claim 6, wherein the step of forming an ion-implanted region comprises:
forming a mask pattern over the semiconductor substrate in the peripheral circuit region; and
performing an ion-implanting process using the mask pattern as a mask.

13. The method according to claim 1, wherein the step of forming an ion-implanted region is performed using a tilt ion implantation process with a tilt angle that implants ions to form a channel region in a portion of the semiconductor that is adjacent the gate electrode and overlaps a portion of the gate electrode in a vertical direction.

14. The method according to claim 13, wherein the step of forming the gate electrode comprises:
forming a gate electrode layer within the trench; and
performing an etch-back process on the gate electrode layer to a depth where, in the subsequent step of forming an ion-implanting region, portions of the first sealing insulating film disposed over the gate electrode and an upper surface of the semiconductor substrate mask the upper surface of the gate electrode.
